(19) United States
(12) Patent Application Publication
(10) Pub. No.: US 2010/0037937 A1
(43) Pub. Date: Feb. 18, 2010

(54) PHOTOVOLTAIC CELL WITH PATTERNED CONTACTS

(76) Inventor: Bernard L. Sater, Strongsville, OH (US)

Correspondence Address: TUROCY & WATSON, LLP, 127 Public Square, 57th Floor, Key Tower, CLEVELAND, OH, 44114, US

(21) Appl. No.: 12/535,952

(22) Filed: Aug. 5, 2009

Related U.S. Application Data
(60) Provisional application No. 61/089,389, filed on Aug. 15, 2008.

(51) Int. Cl. H01L 31/05; H01L 31/18; H01L 21/67

(52) U.S. Cl. 136/249; 438/57; 29/25.01; 257/E31.032

(57) ABSTRACT

Photovoltaic cells and processes that mitigate recombination losses of photogenerated carriers are provided. To reduce recombination losses, diffuse doping layers in active photovoltaic (PV) elements are coated with patterns of dielectric material(s) that reduce contact between metal contacts and the active PV element. Various patterns can be utilized, and one or more surfaces of the PV element can be coated with one or more dielectrics. Vertical Multi-Junction photovoltaic cells can be produced with patterned PV elements, or unit cells. While patterned PV elements can increase series resistance of VMJ photovoltaic cells, and patterning one or more surfaces in the PV element can add complexity to a process utilized to produce VMJ photovoltaic cells, reduction of carrier losses at diffuse doping layers in a PV element increases efficiency of photovoltaic cells, and thus provide with PV operational advantages that outweigh increased manufacturing complexity. System to fabricate the photovoltaic cells is provided.

### CROSS-REFERENCE TO RELATED APPLICATIONS

This application claims the benefit of U.S. Provisional Application Ser. No. 61/089,389, filed Aug. 15, 2008 and entitled “SOLAR CELL WITH PATTERNED CONTACTS,” the entirety of which is incorporated herein by reference.

### BACKGROUND

Limited supply and increasing demand of fossil energy resources and associated global environmental damage have driven global efforts to diversify utilization energy resources and related technologies. One such resource is solar energy, which employs photovoltaic (PV) technology for conversion of light into electricity. In addition, solar energy can be exploited for heat generation (e.g., in solar furnaces, steam generators, and the like). Solar technology is typically implemented in a series of PV cells, or solar cells, or panels thereof that receive sunlight and convert the sunlight into electricity, which can be subsequently delivered into a power grid. Significant progress has been achieved in design and production of solar panels, which has effectively increased efficiency while reducing manufacturing cost thereof. As more highly efficient solar cells are developed, size of the cell is decreasing leading to an increase in the practicality of employing solar panels to provide a competitive renewable energy substitute to dwindling and highly demanded non-renewable sources. To this end, solar energy collection systems like solar concentrators can be deployed to convert solar energy into electricity which can be delivered to power grids, and to harvest heat as well. In addition to development of solar concentrator technology, development on solar cells directed to utilization is solar concentrators has been pursued.

High Intensity Solar Cell technology, referred to as a vertical multi-junction (VMJ) solar cell, is an integrally bonded series-connected array of miniature vertical junction unit cells that are edge illuminated with electrical contacts on the ends. The unique VMJ cell design can inherently provides high-voltage low-series resistance output characteristics, making it ideally suited for efficient performance in high intensity photovoltaic concentrators. Another key feature of the VMJ Cell is its design simplicity that leads to low manufacturing cost.

The efficacy of VMJ can be evidenced on performance data taken on an experimental VMJ cell with 40 series-connected junctions over the range of 100 to 2500 suns intensities where the output power density exceeded 400,000 watts/m² at 25 volts with near 20% efficiency. It should be appreciated that the foregoing performance in VMJ solar cells is accomplished with low manufacturing cost(s) and low manufacturing complexity. Such aspects are believe to be the needed drivers for feasible technical performance and economic efficiencies needed to enable photovoltaic concentrator systems to be significantly more cost effective and viable in solving global energy problems. Furthermore any increase in cell efficiency (e.g., more watts in output) should directly decrease concentrator system size (e.g., less cost associated with bill of materials) resulting in lower $/watt photovoltaic power cost.

It is to be noted that lower $/watt cost is substantially relevant to solar cell technology adoption and market penetration since global energy demand is steadily increasing, not only in emerging but in developed countries as well, while traditional fossil fuel costs are escalating. Also there are widespread increasing concerns for all associated problems; such as environmental pollution, global warming, and national security and economic perils linked with dependency on foreign fuel supplies. These environment, economic and security factors coupled with growing public awareness are driving intense interest in finding more cost-effective and environmentally friendly renewable energy solutions. Of all available renewable energy resources, solar has the substantially greatest potential for satisfying demand in an efficient and sustainable manner. In fact, the earth receives more energy in the form of sunlight every periods of few minutes than mankind can consume from substantially all other resources over an entire year.

Even though photovoltaic power is widely recognized as an ideal renewable energy technology, its associated cost(s) can be a major impediment to adoption and market penetration. Before gaining market share and adoption, photovoltaic-based power needs to become cost-competitive with traditional power sources, including coal-fired power which is well developed, adopted among consumers and substantially cost effective. Moreover access to low cost electrical power is considered essential in all global economies; so terawatts (e.g., thousands of Giga Watts) of photovoltaic power systems can be needed. Market studies show installed photovoltaic power systems must drop to a benchmark cost of $3/watt, or less, before being cost-competitive without subsidies in large utility scale applications. Since installed photovoltaic system costs currently exceed $6/watt, substantial cost improvements are still required.

Attempting to achieve lower $/watt performance has been the principal goal of most research and development in photovoltaic technologies during the past several decades. Despite the industry spending billions of dollars pursuing a variety of technologies with the objective of rendering photovoltaic energy more cost-effective, existing photovoltaic industry still requires substantial subsidies to support sales, which can be an indicator of detrimental conditions for market development and industry development.

Currently silicon solar cells, which remain substantially the same as at the time of initial discovery and development in 1960s, dominate ˜93% of photovoltaic markets. Existing photovoltaic industry in an endeavor to lower costs has relied heavily on the availability of low cost scrap-grade semiconductor silicon to manufacture conventional solar cells. It should be noted that such scrap-grade silicon, often referred to as solar-grade silicon, is primarily the heads and tails of ingots left over from wafer production and off-spec material rejected by semiconductor device manufacturers requiring higher quality prime-grade silicon wafers. Although photovoltaic sales have increased rapidly, growing ˜40% annually over the past decade with production volume estimated at 3.8 Gigawatts (GW) in 2007, sales are now hampered by shortages and higher prices in solar-grade silicon. Although prime-grade silicon is available, it is not considered an option since it would further increase manufacturing costs several fold.

For typical conventional solar cells over half the manufacturing cost is raw semiconductor poly-silicon used to produce the wafers for solar cells. As a result, a typical 14% efficiency solar cell is rated at 0.014 Wcm⁻² and has more than $3/watt (or $0.042/cm²) in silicon wafer cost before any additional manufacturing. Consequently, the existing photovoltaic industry has to address and resolve the fact that starting silicon material cost(s) alone exceeds the benchmark price utilities need for large scale applications. As a contrasting aspect, semiconductor manufacturers producing microprocessor chips that sell at over $100/cm² on an area basis can afford cost(s) associated with utilization of prime-grade silicon wafers.

The shortages in solar-grade silicon and the photovoltaic industry's inability to achieve important benchmark cost, along with the advent of new more efficient triple-junction solar cells developed for space applications, have recently generated considerable renewed interest photovoltaic concentrators. The obvious advantage of photovoltaic concentrators is the potential cost benefit resulting from using large areas of inexpensive materials (glass mirror reflectors or plastic lenses) to concentrate sunlight onto much smaller areas of expensive solar cells, hence using cheap materials to replace expensive materials. Designing photovoltaic concentrators for 1000 suns intensity would significantly reduce expensive semiconductor silicon requirements by ˜99.9%, which means 1000 MW of VMJ cells are possible using same amount of expensive semiconductor silicon currently required for 1 MW of conventional solar cells. Pragmatically, this is considered a practical approach to alleviate any silicon shortage concern.

Substantial work on solar concentrators has mostly focused on developing silicon concentrator solar cell designs for high intensities; much of work considerable developed during the era of the 1970s energy crisis, which at the time demonstrated moderate to unsatisfactory results cost benefits. Research and development initially targeting silicon cells for concentrator systems for operation at 500 suns intensity was conducted; however that target was lowered to 250 suns when unresolved development difficulties were encountered in attempting to overcome series-resistance problems in the solar cell designs being investigated. For example, high series-resistance losses in concentrator solar cells were well recognized as being a major problem, which conventional VMJ solar cell technology has addressed and resolved. It is to be noted that a substantial portion of solar cells developed for concentrator technology are quite complex and expensive to manufacture, with 6 or 7 high-temperature steps (>1000° C.) and 6 or 7 photolithography masking steps. This complexity was attributed to design attempts to minimize series-resistance losses that basically limited maximum intensity operation in the best of these designs to no more than 250 suns. Such complexity and associated costs hindered substantial development of concentrator technologies and associated solar cell technologies, and promoted development of alternative technologies like thin-film solar cell technologies.

Vertical Multi-Junction (VMJ) solar cell technology is substantially different from conventional concentrator solar cells. The VMJ solar cell technology provides at least two advantages with respect to other technologies: (1) it does not require photolithography, and (2) a single high-temperature diffusion step, at temperatures greater than 1000° C., can be employed to form both junctions. Consequently, lower manufacturing cost is a given. In addition, VMJ solar cells can be operated at high intensities; e.g., operation at 2500 suns. It is readily apparent from such operation that series-resistance is not a problem in VMJ cell design; even at intensities an order of magnitude higher conventional wisdom suggested it was not economically viable. Also the current density in VMJ unit cells at 2500 suns is typically near 70 A/cm², a radiation level that can be substantially detrimental to most solar cells based on other technologies.

As stated above, the renewed interest in photovoltaic concentrators is largely due to the development Triple-Junction Solar Cells made with III-V materials containing gallium (Ga), phosphorus (P), arsenide (As), indium (In) and germanium (Ge). Triple-junction cell may use 20 to 30 different semiconductors layered in series upon germanium wafers: doped layers of GaInP₂ and GaAs grown in a metal-organic chemical vapor deposition (MOCVD) reactor where each type of semiconductor will have a characteristic band gap energy that causes it to absorb sunlight most efficiently at a certain color. The semiconductors layers are carefully chosen to absorb nearly the entire solar spectrum, thus generating electricity from as much of the sunlight as possible. These multi-junction devices are the most efficient solar cells to date, reaching a record high of 40.7% efficiency under modest solar concentration and laboratory conditions. But since they are expensive to manufacture, they require application in photovoltaic concentrators.

However the demand and cost of III-V solar cell materials are rapidly increasing. As an example, in 12 months (12/2006-12/2007) the cost of pure gallium increased from about $350 per Kg to $680 per kg and germanium prices increased substantially to $1000-$1200 per Kg. The price of indium which was $94 per Kg in 2002 increased to nearly $1000 per Kg in 2007. In addition the demand for indium is projected to continue to increase with large-scale manufacturing of thin-film CIGS (CuInGaSe) solar cells started by several new companies in 2007. Moreover, indium is a rare element that is widely used to form transparent electrical coatings in the form of indium-tin oxide for liquids crystal displays and large flat-panel monitors. Realistically, these materials appear not viable long term photovoltaic (PV) solutions needed to provide terawatts of low cost power in solving major global energy problems.

While III-V semiconductor solar cell of area 0.26685 cm² may generate a power of 2.6 watts, or about 10 W/cm², and it has been estimated that such technology may eventually produce electricity at 8-10 cents/kWh, substantially similar to the price of electricity from conventional sources, further analysis may be needed to support such estimate. However, VMJ solar cells showed output power exceeding 40 W/cm² at 2500 suns intensity using the least costly semiconductor material with low cost manufacturing. (This output power is over 400,000 W/m².) In addition to complex PV technologies based on advanced materials, Si-based solar cell technology remains substantially dominant in photovoltaic elements and applications. Moreover, should a global need occur, silicon is the only semiconductor material with an existing industrial base that would be capable of supplying terawatts of photovoltaic power within the foreseeable future for widespread global application.

### SUMMARY

The following presents a simplified summary in order to provide a basic understanding of some aspects described herein. This summary is not an extensive overview nor is intended to identify key/critical elements or to delineate the scope of the various aspects described herein. Its sole purpose is to present some concepts in a simplified form as a prelude to the more detailed description that is presented later.

The subject innovation provides semiconductor-based photovoltaic cells and processes that mitigate recombination losses of photogenerated carriers. In an aspect, to reduce recombination losses, diffuse doping layers in active photovoltaic elements are coated with patterns of dielectric material(s) that reduce contact between metal contacts and the active PV element. Various patterns can be utilized, and one or more surfaces of the PV element can be coated with one or more dielectrics. Vertical Multi-Junction (VMJ) solar cells can be produced with patterned PV elements, or unit cells. Patterned PV elements can increase series resistance of VMJ solar cells, and patterning one or more surfaces in the PV element can add complexity to a process utilized to produce VMJ solar cells; yet, reduction of carrier losses at diffuse doping layers can increase efficiency of solar cells and thus provide with PV operational advantages that outweigh increased manufacturing complexity. A system that enables fabrication of the semiconductor-based PV cells is also provided.

Aspects or features described herein, and associated advantages, such as reduction of recombination losses of photogenerated carriers, can be exploited in any class of photovoltaic cells such as solar cells, thermophotovoltaic cells, or cells excited with laser sources of photons. Additionally, aspects of the subject innovation also can be implemented in other class(es) of energy-conversion cells such as betavoltaic cells.

To the accomplishment of the foregoing and related ends, certain illustrative aspects are described herein in connection with the following description and the annexed drawings. These aspects are indicative of various ways which can be practiced, all of which are intended to be covered herein. Other advantages and novel features may become apparent from the following detailed description when considered in conjunction with the drawings.

### BRIEF DESCRIPTION OF THE DRAWINGS

FIGS. 1A and 1B are diagrams of example configuration of patterned surfaces of PV elements in accordance with aspects disclosed in the subject application. FIG. 1C displays a diagram of example set of precursors and derived PV elements that can be produced through doping in accordance with aspects described herein.

FIGS. 2A-2C illustrate diagrams of example configurations of patterned dielectric coating of PV elements and an illustrative VMJ stack in accordance with aspects described herein. FIG. 2D illustrates a VMJ PV cell processed to expose a specific crystalline surface.

FIGS. 3A-3C illustrate diagrams of example configurations of patterned dielectric coating of PV elements and an illustrative VMJ stack in accordance with aspects described herein.

FIG. 4 illustrates a cross-section diagram of an example configuration of patterned dielectric coating of an active PV element with a reduced diffuse doping layer in accordance with aspects described herein.

FIGS. 5A and 5B illustrate diagrams of example configurations of patterned dielectric coatings of a PV element in accordance with aspects described herein.

FIG. 6 presents a perspective illustration of an embodiment of a photovoltaic cell with textured surface in accordance with aspects described herein.

FIG. 7 is a flowchart of an example method for producing a photovoltaic cell with reduced carrier recombination losses according to aspects disclosed herein.

FIG. 8 displays a flowchart of an example method for producing VMJ solar cells with reduced carrier recombination losses according to aspects described herein.

FIG. 9 is a block diagram of an example system that enables fabrication of solar cells in accordance with aspects described herein.

### DETAILED DESCRIPTION

The subject innovation is now described with reference to the drawings, wherein like reference numerals are used to refer to like elements throughout. In the following description, for purposes of explanation, numerous specific details are set forth in order to provide a thorough understanding of the present invention. It may be evident, however, that the present invention may be practiced without these specific details. In other instances, well-known structures and devices are shown in block diagram form in order to facilitate describing the present invention.

In the subject description, appended claims, or drawings, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in the subject specification and annexed drawings should generally be construed to mean “one or more” unless specified otherwise or clear from context to be directed to a singular form.

Moreover, with respect to nomenclature of impurity doped materials that are part of the photovoltaic cells described herein, for doping with donor impurities, the terms “n-type” and “N-type” are employed interchangeably, so are the terms “n+-type” and “N+-type.” For doping with acceptor impurities, the terms “p-type” and “P-type” are also utilized interchangeably, and so are the terms “p+-type” and “P+-type.” For clarity, doping type also appears abbreviated, e.g., n-type is labeled as N, p+-type is indicated as P+, etc. Multi-layer photovoltaic elements or unit cells are labeled as a set of letters, each of which indicates doping type of the layer; for instance, a p-type/n-type junction is labeled PN, whereas a p+-type/n-type/n+-type junctions is indicated with P+NN+; labeling of other junction combinations also adhere to this notation.

The subject innovation relates to improving performance of photovoltaic cells, e.g., solar cells, particularly high-intensity solar cells such as edge-illuminated or vertical junction structures that can produce a substantially high power output under high intensity radiation levels. Various designs of PV elements that form unit cells employed to fabricate VMJ photovoltaic cells are set forth herein unit to reduce recombination losses of photogenerated carriers via patterned contacts.

The VMJ cell has an inherent theoretical limit efficiency exceeding 30% at 1000 suns intensity so further performance improvements are possible using experimental understanding and insight from computer simulations and modeling analysis. Although conventional one-sun solar cells are easily modeled with good results using analytical equations, such is not the case for edge-illuminated VMJ cells at operating at high intensities, because at high intensities, even second order effects can have substantial effect(s) on the cell operating efficiency. While aspects or features of the subject innovation are illustrated with solar cells, such aspects or features and associated advantages, such as reduction of recombination losses of photogenerated carriers, can be exploited in other photovoltaic cells, e.g., thermophotovoltaic cells, or cells excited with laser source(s) of photons. Moreover, aspects of the subject innovation also can be implemented in other classes of energy-conversion cells such as betavoltaic cells.

The physics of electron-hole carrier pairs produced in solar cells at high intensities is rather complex as many physical parameters come into play, including, but not limited to: surface recombination velocities, carriers mobility and concentrations, emitters (e.g., diffusions) reverse saturation currents, minority carrier lifetimes, band gap narrowing, built-in electrostatic fields, and various recombination mechanisms. Mobility decreases rapidly with increasing carrier density and Auger recombination increases rapidly with intensity as the cube of the carrier density. To incorporate such aspects into modeling of VMJ solar cell performance, computer simulations (e.g., two-dimensional numerical computational analysis of photogenerated carrier transport in a semiconductor) can provide insight into physical parameters in vertical junction unit cells, or PV elements, operating or for operation at high intensities. Such simulations provide an analysis and design instrument to understand possible sources of performance efficiencies and to increase performance of VMJ cells at high intensities. It should be appreciated that while even though conventional one-sun solar cells are easily modeled with good results using simple analytical equations, such is not the case for edge-illuminated VMJ photovoltaic cells operating at high illumination intensities, because at high intensities, even second order effects can have a dramatic effect of the cell operating efficiency

Computational simulations based upon models of contact-to-contact VMJ unit cells that incorporate an array of semiconductor physics reveal specific regions in VMJ unit cells where recombination losses of photogenerated carriers occur at high intensities. At least some of such regions present complex loss mechanisms that are intensity dependent. Computer simulation(s) reveal regions in PV elements, or VMJ unit cells, that can be improved upon in order to reduce recombination losses and improve performance of VMJ cells. Aspects of the subject innovation provide such improvements.

Series resistance has been considered a significant source of design issues for conventional concentrator solar cells. The VMJ photovoltaic cell design proved more than adequate in this regard, showing series resistance is not a problem even at 2500 suns intensity. However, in some situations, it can be advantageous to tradeoff an increase in series resistance for less design simplicity, in order to improve efficiency of VMJ photovoltaic cells for photovoltaic concentrators operating near 1000 suns.

It should be appreciated that design for operation at substantially higher intensities, such as 2500 suns where VMJ cells are still capable of operating efficiently, can require substantially more demanding and expensive concentrator system engineering in optics, structures, sun tracking, and thermal control, while not likely contributing any better overall performance or economic benefits. Therefore, aspects or features of solar cells, and associated process(es) for production thereof, set forth in the subject innovation can increase efficiency performance of high-intensity VMJ cells operating in the range of 1000 suns or higher. Efficiency increase can make VMJ solar cells or other solar cells that exploit aspects of the subject innovation more cost effective and viable, even though it can involve additional manufacturing and a potential increase in series resistance for intensities greater than 1000 suns. Aspects or features described herein can provide adequate engineering tradeoffs to make photovoltaic concentrator systems using solar cells, VMJ cells or otherwise, that exploit aspects of the subject innovation more viable and cost effective in providing lower $/watt performance.

Computer modeling analysis of conventional VMJ unit cell design, e.g., P+NN+ slab with deep junctions, using realistic parameters for good silicon processing (minority-carrier lifetimes, surface recombination velocity, etc.) at intensities greater than 500 suns, showed the following percentage recombination losses for some specific regions:
P+ diffusion 22.7%
P+ contact 5.3%
N+ diffusion 32.8%
N+ contact 11.4%

Therefore, this analysis suggests the heavily doped P+ and N+ diffused emitter regions with their metal contacts account for over half of all recombination losses in unit cells that form the VMJ solar cell, and that an optimized diffused N+ emitter may be different in design from an optimum diffused P+ emitter, due in part to differences in mobility. Relative magnitude of recombination losses originated in N+ and P+ regions can be switched for N+PP+ unit cell(s), or P+NN+ unit cell(s) with shallow P+N junction(s). In an aspect, the subject innovation is directed to reducing recombination losses in the foregoing diffusion regions in order to improve the performance of VMJ cells.

High minority-carrier lifetimes and low surface recombination velocities were successfully achieved in conventional VMJ cell development with open-circuit voltage V_{oc}=0.8 volts per unit cell junction at high intensities. V_{oc} is determined by sunlight-generated currents and diffused emitter reverse saturation currents (Jₒ), with both the P+N and NN+ junctions present in the unit cell(s) of a VMJ solar cell contributing to the open-circuit voltage. The optimum junctions from an electrical point of view are the lowest Jₒ; using Jₒ=1×1⁻¹³ Acm⁻², which is representative of high-quality low reverse saturation currents in diffused junctions, the analysis showed diffusion depths of approximately 3 to 10 μm are sufficient depths for both the P+ and N+ diffusions, even when considering infinite recombination velocities at the ohmic metal contacts.

It is to be noted that even though deep and gradual NN+ diffusion profiles will provide a built-in electrostatic drift field that will enhance the minority carrier movement towards the junction barrier for ultimate collection and reduce recombination in this region, computer simulations reveal NN+ junction enhancement becomes less effective at high intensities, which can result in higher recombination in N+ region as shown above.

Experiments and computational modeling and simulation have identified that prime areas for improving performance are in reducing recombination losses in the heavily doped P+ and N+ diffused and metal contacts regions for VMJ unit cells operating at high intensities. Since a high-quality oxide passivated surface can have a recombination velocity as low as a few cm/second, which is significantly less than that at the metal contacts, and considering that the drift fields created by diffusion profiles become less effective at high intensities, aspects of the subject innovation provide reduced metal contact area and diffusion area via patterned dielectric coating of PV elements, or VMJ unit cells, to improve performance of VMJ solar cells.

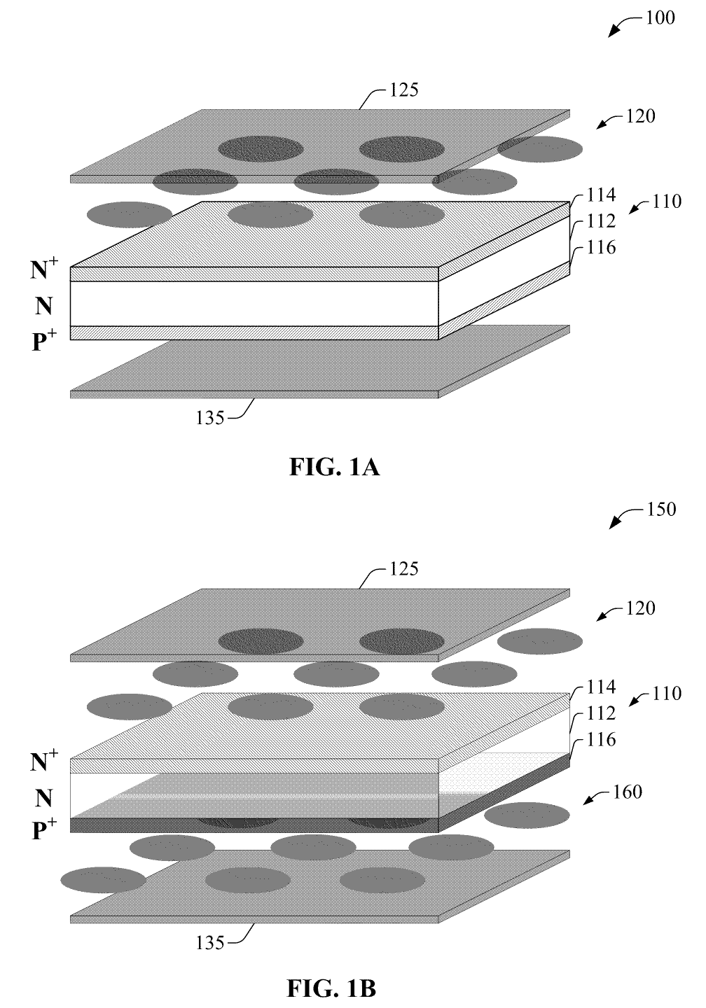

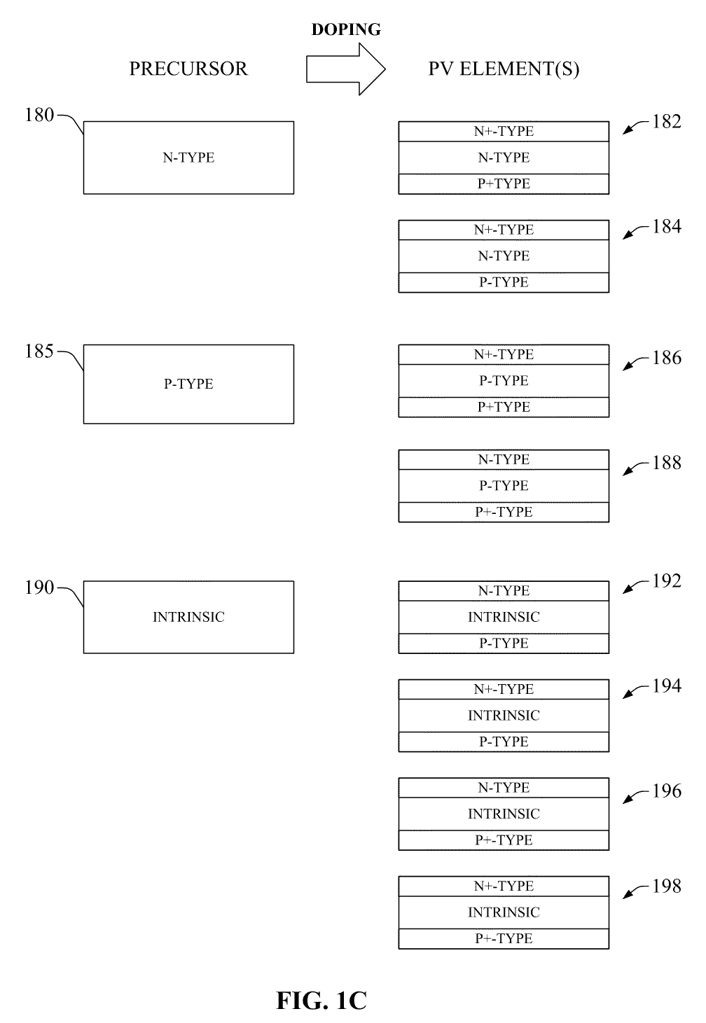

With respect to the drawings, FIG. 1A illustrates a diagram 100 of a photovoltaic element 110 with a patterned dielectric coating 120 between one of the surfaces of the PV element and a metal contact 125. Note that surfaces of PV element 110, dielectric coating 120, and metal contact 125 are illustrated as not in contact for clarity. However, in solar cell(s) discussed herein, such surfaces are in contact. Pattern dielectric coating 120 is illustrated as disconnected elliptical regions assembled in a periodic array or lattice. The PV element 110 is typically a slab of N-type semiconductor material, wherein the semiconductor material is one of Si; Ge; GaAs, InAs, or other III-V semiconducting compounds; II-VI semiconducting compounds; CuGaSe; CuInSe; CuInGaSe. The slab can include a doped P+ diffuse region 116 (labeled as P+) on a first surface of the slab and a doped N+ diffuse region 114 (labeled as N+) on a second surface substantially parallel to the first surface. Thickness of the active PV element 110 affords an N-type (N) layer 112 among the diffused doped layers 114 and 116. Thickness of diffusion layers 114 and 116 can range from 3-10 μm, and are determined by doping process employed to introduce carriers into a slab of N-type material (e.g., slab 112). Inclusion of diffuse doped layers can be accomplished with substantially any doping means, e.g., techniques and dopant materials, typically employed in semiconductor processing. Dopant materials can include phosphorous and boron, for N+ and P+ doping, respectively. For purposes of explanation, interfaces between diffuse layers N+ 114 and P+ 116 and N-type (N) layer 112 are idealized as sharp abrupt boundaries; however, such interfaces can be irregular, with areas of intermixing between neutral and doped materials. The degree of intermixing dictated, at least in part, by the mechanisms or means employed to generate the doped diffuse regions.

While aspects or features of the subject innovation are illustrated for an initially N-type slab of semiconductor material as precursor of PV element 110, such aspects or features can also be implemented or accomplished in an initially intrinsic, e.g., nominally undoped, precursor of PV element 110. Moreover, in alternative or additional scenarios, P-type precursor(s) can be employed: PV element 110 can be a slab of P-type doped semiconductor material that can include P+ diffuse layer 116 on a first surface, and its vicinity, of the slab and N+-doping diffuse layer 114 a second surface, and its vicinity, substantially parallel to the first surface, as described supra.

In an aspect of the subject innovation, patterned dielectric coating 120 reduces formation of metal-diffuse doping layer interface (e.g., metal and N+ layer 114 interface) upon metallization of active PV element 110—openings in a patterned dielectric coating are the regions where the metal and diffuse doping layer form an interface. Since such interfaces have high recombination losses, the reduction of the metal-diffuse doping layer contact thus mitigates nonradiative losses of photogenerated carriers (e.g., electrons and holes), with ensuing increase in photovoltaic efficiency of PV element 110. In addition, coating a PV element, e.g., 110, with dielectric material produces passivation of surface states and thus reduces surface recombination losses. Patterning of dielectric coating can be accomplished through photolithographic techniques, or substantially any other technique that allows controlled patterning of a dielectric surface; for instance, wet etching. Such photolithographic techniques generally afford pattern formation through multiple processing steps of masking and removal of the dielectric material in the dielectric coating. Alternatively or additionally, patterning of dielectric coating can be accomplished through deposition techniques, e.g., vapor coating like chemical vapor deposition (CVD) and its variations, plasma etched CVD (PECVD); molecular beam epitaxy (MBE), etc., in the presence of a mask that shadows deposited material in order to dictate a specific pattern.

It should be appreciated that dielectric coating layer 120 can adopt various planar geometries and configurations that provide electrical contact among N+-doping diffuse layer 114 and metal contact 125. As indicated supra, in example diagram 120, dielectric coating 120 adopts a square-lattice arrangement of elliptical disconnected areas. Other lattices of dielectric regions also can be formed. Such lattices can include triangular lattice, monoclinic lattice, face-centered square lattice, or the like. Alternative or additional arrangements of portion(s) of dielectric material within a patterned dielectric coating can include disconnected or connected stripes of dielectric material. It is to be noted that a patterned dielectric coating, such as coating 120, can be placed among metal contact 135 and P+ diffuse doping layer 116 (see, e.g., FIG. 1B). Location of patterned dielectric coating 120 is dictated by the neutral-doped junction that has dominant losses at operating radiation intensity in a solar concentrator or other solar-electric energy conversion apparatus or device. For example, in PV element 110 (e.g., a P+NN+ unit cell), N+ diffused region, or layer, and its contact to metal 125 can have substantially larger losses at high electromagnetic radiation intensities, thus patterned dielectric coating 120 in the configuration displayed in diagram 100 can be the substantially least expensive configuration to reduce recombination (e.g., radiative and nonradiative) losses and improve performance of the PV element 110, particularly at high intensities.

It should be appreciated that substantially any pattern of dielectric material (e.g., a disconnected array of openings, such as the space between dielectric elliptic areas in dielectric coating 120) can reduce recombination losses at a single diffuse layer (e.g., N+ layer 114) because metallization applied in a later step can assure all or substantially all open, contact areas are mutually connected when fully bonded to the next planar unit cell within the VMJ cell structure. Unit cell(s) employed to produce a VMJ photovoltaic cell as described herein consist of PV element 110 coated with a dielectric pattern and metalized as described supra. Thus, such unit cell(s) are different from conventional unit cell(s) employed for fabrication of conventional VMJ solar cells. It is noted that smaller contact area(s) amongst metal and doped layer may contribute to an increase in series resistance in a stack of PV elements such as 110 that form a solar cell; thus, an advantageous pattern for reducing the contact area ratio is a high density of closely spaced smaller openings for optimizing performance for a given intensity. Recombination losses can include radiative or nonradiative recombination of photogenerated carriers, wherein nonradiative recombination can comprise Auger scattering, carrier-phonon relaxation, or the like. Auger recombination rate increases as the cube of carrier density, e.g., density of photogenerated carriers; doubling the volume of a photovoltaic device can lead to a sixteen-fold increase in recombination losses when Auger bulk scattering in accounted for. Thus, thinner slabs 110 or substantially any design modification that renders PV element 110 thinner, such as the use of light trapping with textured surfaces, such as V-grooved surfaces, U-grooved surfaces . . . , or back side reflectors, can be utilized to mitigate bulk Auger recombination at high intensities through reduction of the thickness of unit cells that form a VMJ photovoltaic cell. Collection efficiency in PV cells can increase significantly when VMJ unit cells as designed in accordance with aspects described herein afford a 50% reduction in recombination losses.

It should be appreciated that substantially any dielectric material can be employed for dielectric coating 120. In an aspect, dielectric coating can be a thermal oxide layer, which has a low surface recombination velocity. It should further be appreciated that making electrical contacts to end of unit cells, or PV elements, of semiconductor-based (e.g., Si-based) VMJ photovoltaic cells with patterned openings in the dielectric can require a full electrical contact that can be provided by low resistivity silicon that thermally matches or substantially matches the thermal expansion coefficient of the unit cells, or a metal such as molybdenum or tungsten which have thermal coefficient(s) that nearly matches the thermal coefficient(s) of silicon. Likewise, for a VMJ solar cell based on a semiconductor material or compound other than silicon, metallization of patterned dielectric coating, e.g., 120 or 160, can be effected with conductive material(s), e.g., metals or low-resistivity doped semiconductors, that have thermal coefficient(s) that nearly matches thermal coefficient(s) of semiconductor material of the unit cells that form the VMJ solar cells.

With respect to metal layers, metal contact layer 125 and metal contact layer 135 can be disparate. For example, a first metal contact layer (e.g., layer 125) can include dopants, and a second contact layer (e.g., layer 135) can incorporate a diffusion barrier in order to mitigates autodoping.

FIG. 1B is a diagram 150 of a photovoltaic element 110 with patterned dielectric coatings in both diffusion doping regions. In diagram 150, a first patterned dielectric coating 120 between a N+ diffuse doping layer 114 and a first metal contact 125, and a second patterned dielectric coating 160 between a P+ diffuse doping layer 116 and a second metal contact 135. Aspects of dielectric coating 160 are substantially the same as those of dielectric coating 120. As mentioned above, metal contact layer 125 and 135 can be disparate.

It is to be noted that mitigation of recombination losses of photogenerated carriers and ensuing increased PV element performance provided by the introduction of the second patterned dielectric coating outweighs the added complexity and possible extra expense(s) of additional processing act(s) associated with preparation of a second patterned dielectric coating.

To ensure efficient operation of PV element 110 in a photovoltaic device, the first pattern in dielectric coating 120 is to be correlated with the second pattern in coating 160 so as to have a set of one or more opening(s), and section(s) of metal layers 125, in opposition. When patterned dielectric coating 120 is “out-of-phase” with respect to patterned dielectric coating 160, and the dielectric coatings mutually occlude section(s) of respective metal layers 125, resistance among unit cells in a stack of PV elements 110 increases and efficiency of a VMJ solar cell decreases.

Additionally or alternatively, openings formed through pattern dielectric coating 120 can be different in size, e.g., different area, that openings generated via dielectric coating 160. For instance, it can be more desirable to have the openings area for the N+ contacts wider than those for the P+ contacts in PV element 110, or P+NN+ unit cells, to more effectively reduce overall losses, particularly if there are higher losses at the N+ diffused region and metal contacts. As described above, such disparate among opening sizes can be implemented or exploited irrespective of the particular pattern of the dielectric coating.

FIG. 1C displays a diagram of example set of precursors and derived PV element(s) that can be produced through doping in accordance with aspects described herein. As indicated supra, three precursor types can be employed to produce PV elements that are processed to introduce patterned dielectric coating(s) and metal contact(s) as described herein: (i) N-type doped precursor 180, (ii) P-type doped precursor 185, and (iii) intrinsic precursor 190. Precursors are semiconducting materials such as Si; Ge; GaAs, InAs, or other III-V semiconducting compounds; II-VI semiconducting compounds; CuGaSe; CuInSe; CuInGaSe. Upon doping, N-type precursor 180 can lead to PV element 182, which includes an N+-type diffuse doping region and a P+-type doping region, such PV element is PV element 110. In addition, doping of precursor 180 can lead to PV element 184, with layers, or regions, of N-type and P-type diffuse doping. Precursor 185 enable formation of PV elements 186 and 188, with N+ and P+ diffuse doping layers in PV element 186, and N+ diffuse doping and P-type doping in element 188. Various doping of intrinsic precursor 190 result in PV elements 192-198. In PV element 192, P-type and N-type regions of doping are included; PV element 194 includes N+-type and P-type doping layers; PV element 196 includes N-type and P+-type doping layers; and N+-type and P+-type layer are included in PV element 198. While the different regions of doping introduced in the precursor materials 180, 185, and 190 are illustrated as extended regions, such regions can be spatially confined or nearly-confined, as described herein. The various PV elements illustrated herein can be coated with a patterned dielectric material and metalized as described herein in order to form unit cell(s) that can stacked to produce a monolithic photovoltaic cells in accordance with aspects of the subject innovation. In an aspect, patterned contacts formed through coating with patterned dielectric material in P+NN+ PV elements, or unit cells, can be employed for terrestrial PV concentrators, whereas P+PN+ PV elements, or unit cells, can be more radiation hardened and thus exploited for space applications.

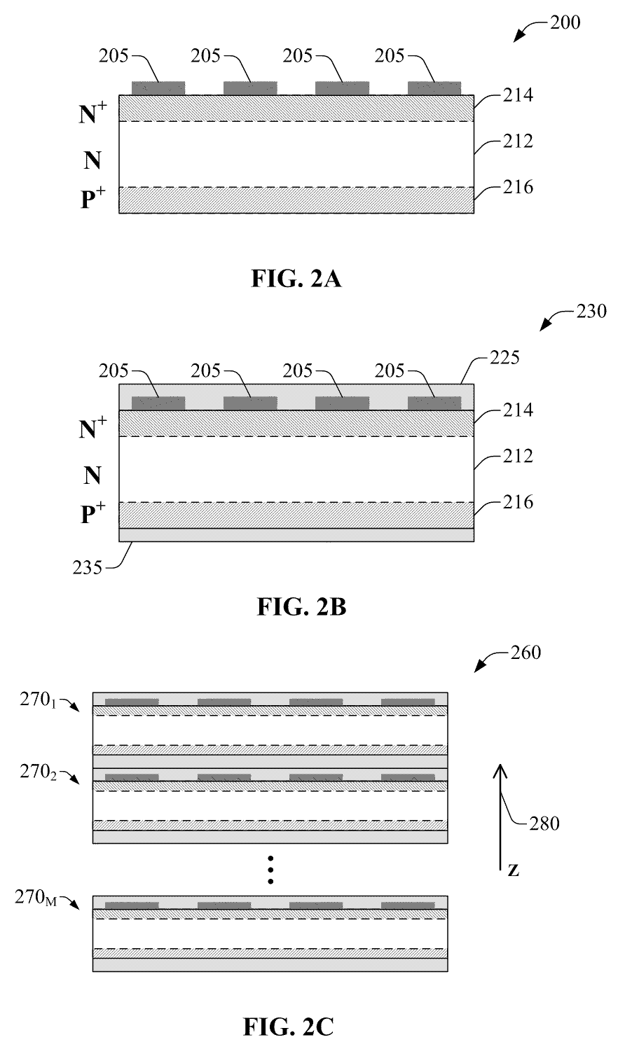

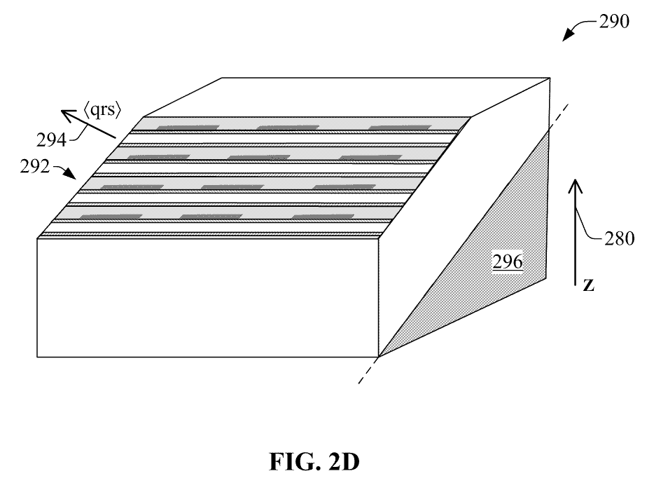

FIG. 2A is a diagram 200 of a cross section of a PV element with a single surface patterned with a dielectric coating. The pattern of dielectric material results in sections 205 of dielectric deposited atop an N+ diffuse doping layer 214. It is to be noted that an additional, or alternative, configuration of a PV element with a patterned dielectric coating on P+ diffuse doping layer 216 is possible. In PV element illustrated in diagram 200, an N-type region 212 separates diffuse doping regions 214 and 216. As discussed above, such configuration can be effective at mitigation of recombination losses associated with operation of the PV element at high intensity.

FIG. 2B illustrates PV elements of diagram 230 upon metallization with metal contacts 225 and 235. The presence of the patterned dielectric coating regions 205 on N+ diffusion layer 214 reduce the electric coupling among electric contacts 225 and 235. As discussed above, metal contact layers can be disparate.

FIG. 2C illustrates an example embodiment of a VMJ photovoltaic cell 260 in which constituent unit cells 270₁-270_{M} (M is a positive integer) stacked along direction 280 exploit a one-side, asymmetric patterned dielectric coating (e.g., coating with dielectric regions 205) on N+ diffuse doping layer. The VMJ solar cell that results from the stack of unit cells 270_{λ} (λ=1, 2 . . . M), which are PV elements, is a monolithic (e.g., integrally bonded), axially oriented structure. In an aspect, based on semiconducting material of unit cell(s), two classes of VMJ photovoltaic cells can be formed: (a) homogeneouse and (b) heterogeneous. In (a), units cell(s) 270₁-270_{M} are based on the same or substantially the same precursor, whereas in (b) the unit cell(s) are based on disparate precursors. Disparate precursors can be based on the same semiconducting compounds, e.g., Si; Ge; GaAs, InAs, or other III-V semiconducting compounds; II-VI semiconducting compounds; CuGaSe; CuInSe; CuInGaSe, but differ in doping type or, for alloyed compounds, in alloying concentrations. Heterogeneous VMJ photovoltaic cells can exploit various portions of the emission spectrum of a source of electromagnetic radiation, e.g., solar light spectrum. A VMJ solar cell can produce a serial voltage ΔV≅M·ΔV_{C} along direction 280, wherein ΔV_{C} is a voltage in a constituent PV element 2702_{λ}. In an aspect, M˜40 is typically utilized to form a VMJ solar cell. A 1 cm² VMJ with M˜40 can output nearly 25 volts under typical operation conditions, such as incident photon flux, radiation wavelength, temperature, or the like. It should be appreciated that performance of a stack of PV elements is limited by the PV element with lowest performance because such element is a current output bottleneck in the series connection; namely, the current output is reduced to the current output of the lowest performing unit cell. Therefore, to optimize performance, stacks of active PV elements, or unit cells, that form the VMJ photovoltaic cell can be current-matched or nearly current-matched based on a performance characterization conducted in a test-bed under conditions (e.g., radiation wavelength(s), concentration intensity) substantially similar to those expected under normal operating conditions of a solar collector system in the field. The current that is matched is current produced by a PV element, or unit cell, upon solar-electric energy conversion.

In addition, the monolithic stack of PV elements 270₁-270_{M} that produces the VMJ solar cell can be processed, e.g., sawn, cut, etched, peeled, or the like, in order to expose or nearly expose a specific crystalline plane (qrs), with q, r, s Miller indices, which are integer numbers, to sunlight when the VMJ solar cell is part of a PV module or device. In an aspect, to achieve substantive passivation of surface states, specific crystalline plane(s) can (100) planes. FIG. 2D illustrates a VMJ PV cell 290 produced through a stack of PV elements, or unit cells, 292 with patterned contacts in the fashion presented in FIG. 2C, the VMJ PV cell processed to expose a specific crystalline surface (qrs), indicated with a normal vector 294 oriented in direction <qrs>. It is noted that any PV elements with patterned contacts described herein can be utilized to form a VMJ PV cell that exposes crystalline plane (qrs). In addition, as part of the processing, and based on direction <qrs>, a portion 296 of the VMJ PV cell can be removed to generate a flat surface to facilitate or enable utilization of the VMJ PV cell in a PV device or module.

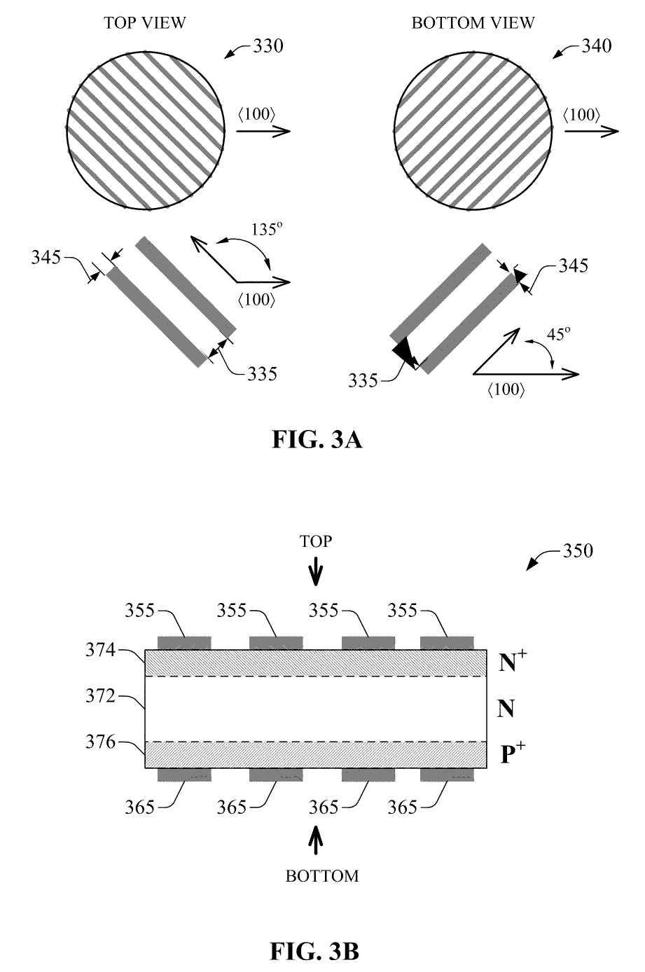

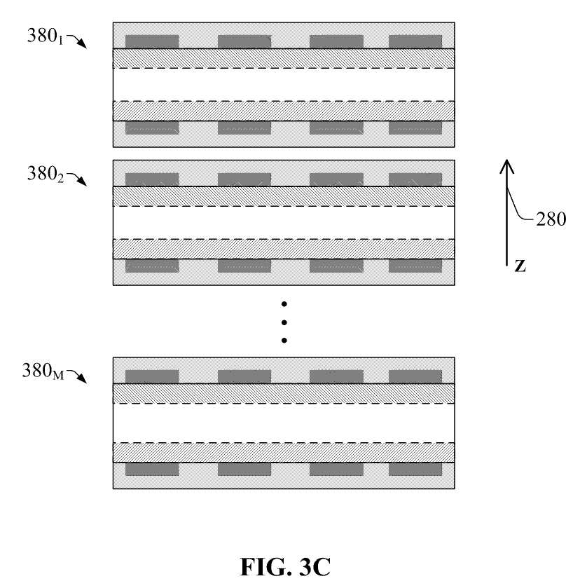

FIG. 3A is a diagram that illustrates example dielectric coating pattern(s) to a PV element. Patterns 330 and 340 correspond to patterns for a first and second surface in a PV element. Openings in the dielectric coating are lines, or stripes, with a defined width w 335 and pitch separation w_{P} 345 from each other. In an aspect, such structure of openings in pattern dielectric coating provide a reduction in contact area of (1+w/w_{P})⁻¹; for instance, when w=w_{P} the reduction there is a 50% reduction in contact area. However, because smaller contact area may contribute to an increase in series resistance, the preferred pattern of lines, or stripes, for reducing the contacts area ratios are high density of closely spaced smaller lines, or stripes, openings. The density can be varied to optimize performance for a given radiation intensity at which the PV element is expected to operate as part of a solar cell, or PV cell, in a PV module. Additional or alternative patterns on opposite surfaces of a PV element 110, or a wafer, also are possible as well as advantageous. As illustrated, lines, or stripes, openings can be made on opposite sides of each PV element 110, or a wafer, and misoriented 90 degrees from one side to the other; namely, stripes in patterned dielectric coating 330 are oriented at an angle of 135 degrees with respect to the <100> direction, whereas stripes in patterned dielectric coating 340 are aligned at an angle of 45 degrees with respect to <100>. It is noted that other relative misorientations are also possible and advantageous. Moreover, as indicated above, openings formed through patterned dielectric coating 330 can be different in size, e.g., span a different area, that openings generated via dielectric coating 340. For instance, it can be generally more desirable to have openings area for the N+ contacts wider than those for the P+ contacts in a PV element with P+NN+ unit cell(s), to more effectively reduce overall losses, particularly when there are higher losses at the N+diffused region and metal contacts. In the alternative, it can be desirable to implement openings area for the P+ contacts wider than those for the N+ contacts to mitigate recombination losses in N+PP+ unit cell(s) (e.g., PV element 186).

At fabrication of vertical multi-junction solar cell(s), which includes stacking and alloying surface-patterned PV elements described herein, the differently oriented, dielectric areas when bonded together with metallization can form low-resistance contact points in a defined pattern. In an aspect, the contact points, facilitated through the openings in dielectric coatings 330 and 340, are directly aligned and mutually adjacent in a controlled pattern, with P+ contacts of one wafer interfacing at points to N+ contacts of the next wafer in order to keep series resistance low in finished VMJ cells. As described supra, in an aspect, fabricated VMJ cells can be sawn to have a preferred <100> crystal orientation at the illuminated surface in order to establish the lowest surface states for passivation. Thus, as illustrated in the FIG. 3A, relative orientation of the lines, or stripes, on a first surface of a patterned PV element can be relatively misoriented at an angle γ such as 90 degrees from the lines or stripes in a second surface, wherein the first and second surfaces include the <100> crystal direction, e.g., are normal to the (100) crystalline plane. Other orientations of lines or stripes are also possible and advantageous. Likewise, relative misorientation γ of lines or stripes at different surfaces can be implemented. In an aspect, misorientation γ is a finite real number; e.g., dielectric coating patterns are not mutually aligned at disparate surfaces. Additionally, since VMJ photovoltaic cells described herein can be processed to expose or substantially expose any crystalline plane (qrs), stripes in a dielectric coating can be oriented at an angle a with respect to crystalline directions <qrs>, with q, r, and s Miller indices. In particular, stripes in a patterned dielectric coating on a first surface can include stripes oriented at a first angle α with respect to <qrs>, whereas stripes in a patterned dielectric coating in a second surface can be oriented at a second angle β (α≠β) with respect to <qrs>; thus, providing a misorientation γ=α−β.

FIG. 3B illustrates a cross-section diagram of a PV element 350 with dielectric coating patterns deposited on both a P+ diffuse doping layer 376 and an N+ diffuse doping layer 374. In PV element 350, N-type region 372 separates diffuse doping regions 214 and 216. The illustrated cross section is a cut that illustrates alignment of dielectric regions on a first surface, e.g., dielectric regions 355, with those dielectric regions on a second surface, e.g., dielectric regions 365. It should be appreciated that other cross-section cuts can display misaligned regions of dielectric material the first surface and second surface. As discussed above, such alignment facilitates to retain series resistance among PV elements 350 when stacked to form a VMJ solar cell, since metal contact in P+ diffuse doping layer can match a metal contact in a subsequently stacked N+ diffuse doping layer, as illustrated in FIG. 3C. It should be appreciated that, as indicated above, spacing amongst dielectric regions 355 can be different from spacing amongst dielectric regions 365.

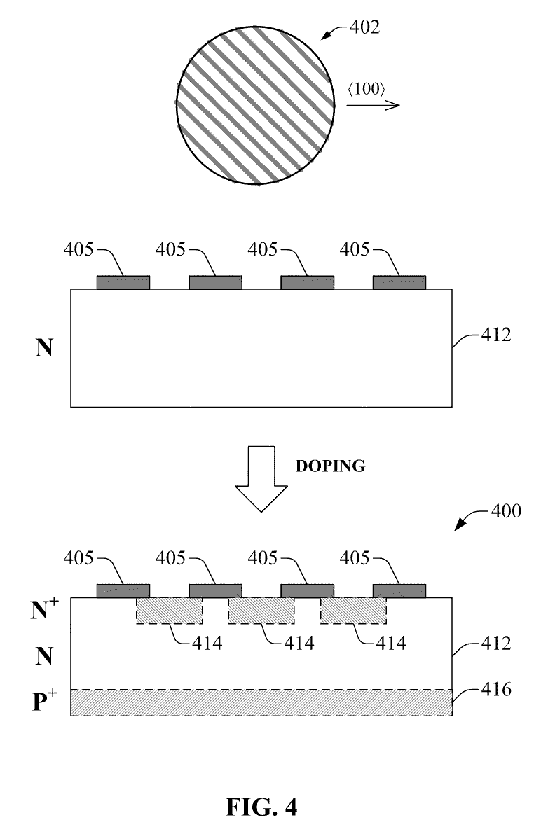

FIG. 4 illustrates a cross-section diagram of an example PV element 400 with dielectric coating regions 405, originated through deposition of patterned dielectric coating 402, that facilitate or enable to reduce at least one of a metal contact area in a surface of the PV element upon metallization thereof. In PV element 400, N+ diffusion region(s) 414 is structured to reduce doping layer volume and thus mitigate recombination losses of photogenerated carriers. Regions of N+ doping can be determined by the openings structure in the patterned dielectric coating; e.g., N+ diffuse region(s) 414 can be stripes oriented along pitch spacing(s) in a striped pattern of dielectric coating 402. Such regions are formed through utilization of dielectric coating regions 405 as a mask to control or manipulate N+ doping. Based at least in part on the patterned dielectric coating 402, and topology of deposited regions 405, N+ diffuse doping area(s) or volume(s) 414 can be fully confined or quasi-confined, e.g., confined in two or less directions and extended in a third direction. In a feature of PV element 400, regions of N-type material 412 are interspersed with N+ diffuse doping regions 414. In addition, P+ diffuse doping region 416 is not coated with a patterned dielectric material.

Upon metallization, e.g., surface of P+ diffuse layer 416 and patterned surface of confined, disconnected N+ diffuse doping region (e.g., set of regions 414) are coated with a metal contact, a set of metalized PV elements can be stacked, and processed, e.g., soldered or alloyed through a high temperature manufacture step, to form a VMJ photovoltaic cell with reduced recombination losses in accordance with aspects described herein.

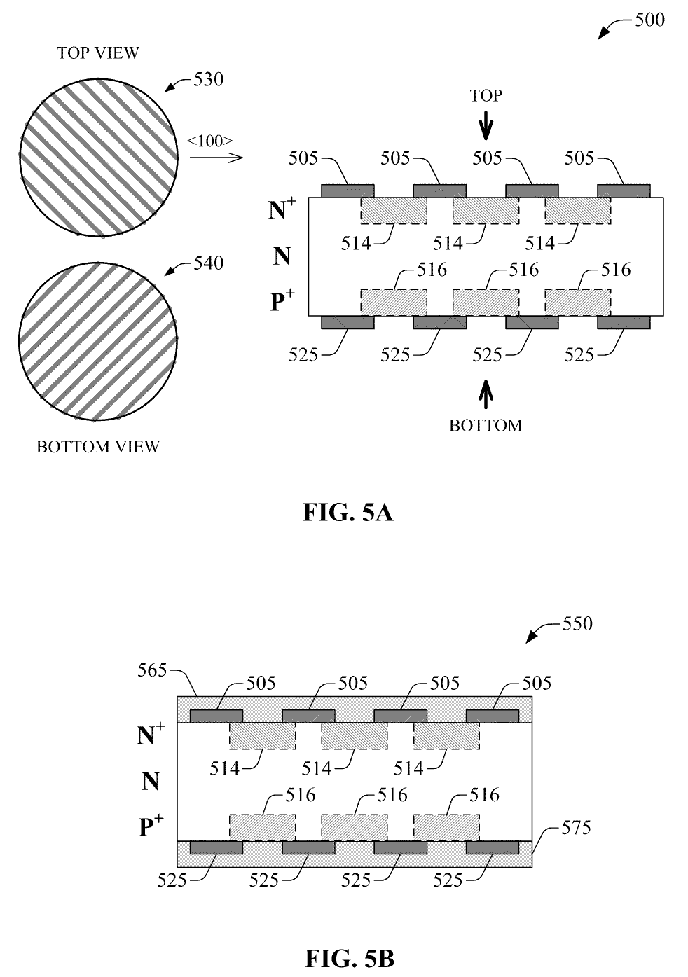

FIG. 5A illustrates a cross-section diagram of a PV element 500 with dielectric coating patterns deposited on opposed diffuse doping regions. In an aspect, a first dielectric coating pattern (e.g., a striped pattern 530 oriented along a direction 135 degrees rotated with respect to the <100> crystalline direction) is utilized to reduce metal contact surface at a first diffuse doping region, while a second dielectric coating pattern (e.g., a striped pattern 540 oriented 45 degrees with respect to the <100> crystalline direction). Both N+ and P+ diffuse doping regions can include, respectively, doping regions 514 and 516 confined in two or more directions. Openings in the dielectric coating patterns can serve as masks to generate reduced-volume doping diffuse layers; the openings formed between regions 505 and 525 of coated dielectric. Reduction of metal contact surface and volume of doping regions at both diffuse doping layers can provide enhanced mitigation of carrier recombination losses with respect to dielectric coating and doping volume reduction in a single doping region. As discussed above, benefit of improved PV performance of a VMJ produced with patterned PV elements, or unit cells, surpass additional processing complexity and costs associated with surface patterning. Moreover, openings formed through pattern dielectric coating 530 can be different in size, e.g., span a different area, than openings generated via dielectric coating 540, in order to further control recombination losses originated from diffuse doping areas. For instance, it can be more desirable to have openings that produce larger N+ doping regions than those that produce P+ doping regions, to more effectively reduce overall losses, particularly when there are higher losses at the N+ diffused region and metal contacts.

FIG. 5B illustrates a cross-section of patterned PV element 550 with metal contact layers 565 and 575, which can be mutually different as discussed above. The illustrated cross-section cut displays metal regions 565 (e.g., among spaces of dielectric material) on the surface of N+ diffuse doping layer aligned with metal regions 575 (e.g., region among spaces of dielectric material) on the surface of P+ diffuse doping layer. In PV element 550, doping regions are formed in an N-type precursor. A set of patterned PV elements 550 can be stacked and processed to form VMJ solar cells with improved performance.

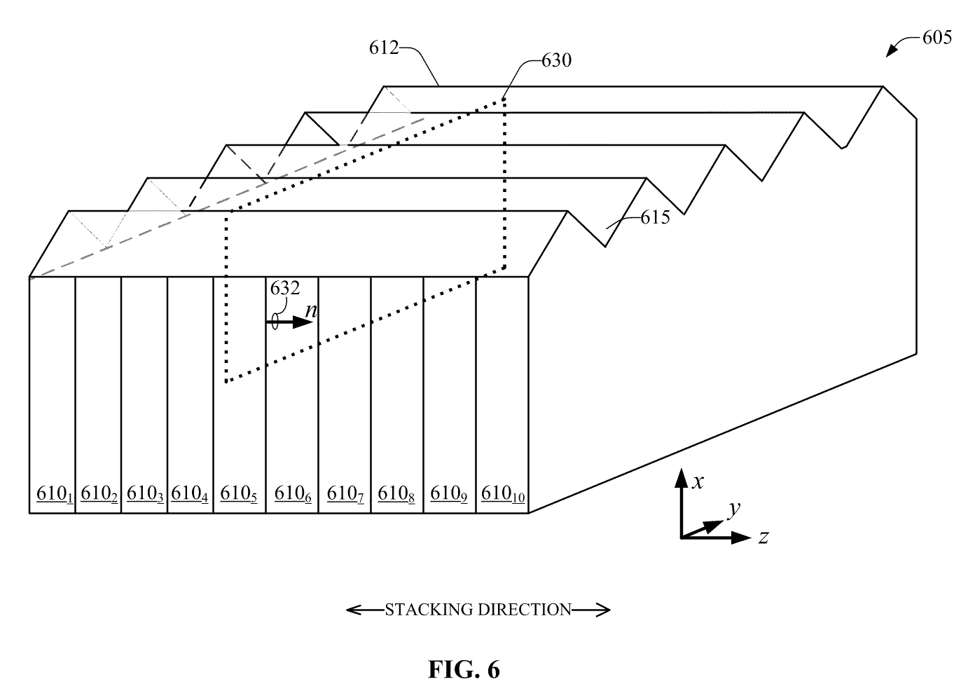

FIG. 6 presents a perspective illustration of an example embodiment of a textured vertical multi-junction (VMJ) photovoltaic cell 605 with textured surface and that is formed by stacking unit cells 610₁-610₁₀ along a direction normal to the plane of the unit cell(s); each unit cell(s) 610_{κ}, with κ=1, 2, . . . 10, consists of a PV element with a patterned dielectric coating and metal contact, as described herein. While in example textured PV cell 605 a set of 10 unit cell(s) are illustrated, it is noted that textured VMJ photovoltaic cells can comprise M unit cell(s), with M a positive integer. Unit cell(s) in a texture VMJ photovoltaic cell, e.g., 610_{κ}, can be embodied in unit cell(s) 270_{λ}, 380_{λ}, or 550, or any other unit cell(s) produced as described herein. In photovoltaic cell 605, textured surface 612 is a V-grooved surface; however, other grooves or cavities of various shapes can be formed, e.g., U groove. The textured surface is formed onto a plane (qrs) that is exposed or substantially exposed to electromagnetic radiation as a result of processing the monolithic stack of unit cell(s), or PV elements with patterned metal contacts described herein; see, e.g., FIG. 2D. Incident light can be refracted in the plane 630 having a normal vector n 632. Such plane 630 is parallel to the surface(s) of unit cell(s) 610_{κ} onto which the patterned dielectric material is coated, and can include the cross section configuration of the grooves 615—plane 630 is substantially perpendicular to the direction of stacking unit cells 610_{λ}. Texturing of surface of the monolithic stack of unit cell(s) 610_{κ}, which leads to textured surface 612, enables the refracted light to be directed away from the P+ and N+ diffuse doping regions without hindering photogeneration of carriers, thus effectively making the unit cells that compose the textured photovoltaic cell 605 thinner, and reducing recombination losses as indicated supra. Moreover, an anti-reflection coating can be applied to the textured surface 610 to increase incident light absorption in the cell.

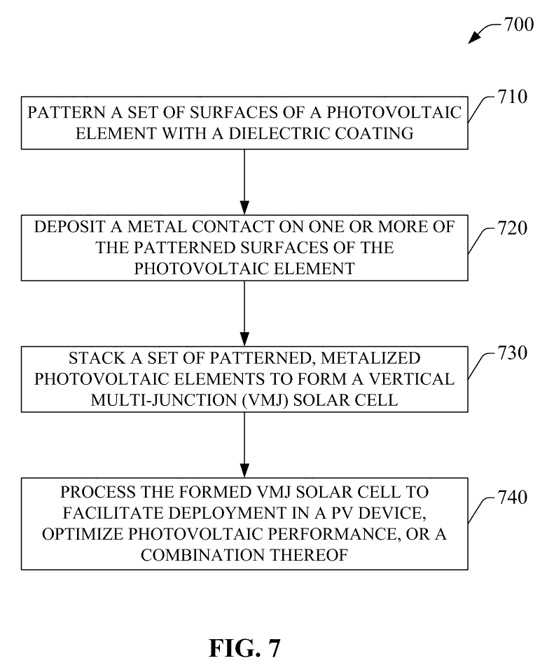

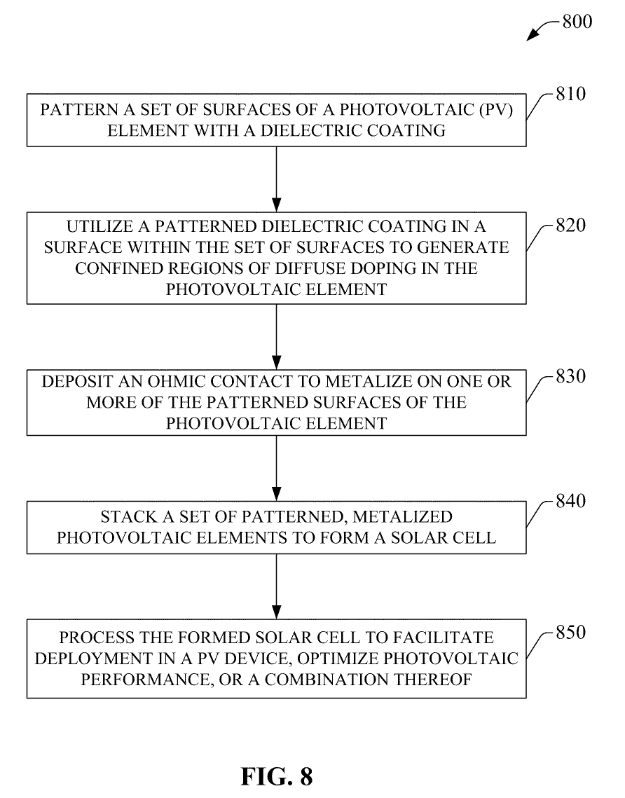

In view of the example systems and elements described above, example methods that can be implemented in accordance with the disclosed subject matter can be better appreciated with reference to flowcharts in FIGS. 7-8. For purposes of simplicity of explanation, the methods described set forth herein are presented and described as a series of acts; however, it is to be understood and appreciated that the described and claimed subject matter is not limited by the order of acts, as some acts may occur in different orders and/or concurrently with other acts from that shown and described herein. For example, it is to be understood and appreciated that a method described herein can alternatively be represented as a series of interrelated states or events, such as in a state diagram, or interaction diagram. Moreover, not all illustrated acts may be required to implement example method in accordance with the subject specification. Additionally, the example methods described herein can be implemented conjunctly to realize one or more features or advantages.

FIG. 7 is a flowchart of an example method 700 for producing VMJ solar cells with reduced carrier recombination losses according to aspects disclosed herein. The subject example method is not limited to solar cells and it also can be effected to produce any or substantially any photovoltaic cell. One or more component(s) or module(s) described herein can effect the subject example method 700. At act 710, a set of surfaces of a photovoltaic element (e.g., PV element 110) are patterned with a dielectric coating. Patterning the PV element with the dielectric coating includes utilizing any suitable technique for produce one or more of the dielectric coatings discussed supra. As an example, patterning can proceed through deposition and photolithography techniques. As another example, etching techniques can also be employed to complement or supplement employed patterning protocols. Substantially any or any dielectric material can be employed to coat the set of surfaces. At act 720, a metal contact is deposited onto one or more of the patterned surfaces of the PV element. Alternative or additional realization of act 730 can include deposition of an ohmic contact or conductive contact onto the one or more of the patterned surfaces of the PV element. The material for the metal contact, or ohmic contact, can be embodied in substantially any or any conductive material, e.g., a low-resistivity doped semiconductor or a metal. In an aspect, the conductive material preferably has thermal coefficient(s) that nearly matches thermal coefficient(s) of semiconductor material of the PV element. In another aspect, the conductive material has bonding characteristics that facilitate stacking of patterned and metalized PV elements. In yet another aspect, pattern(s) of dielectric material coating(s) ensures that metallization of opposing surfaces results in regions of low resistance by aligning metal regions on disparate surfaces (e.g., 90 degree-misoriented striped openings in patterns 530 and 540 result in metal contact regions aligned along a stacking direction (e.g., z direction 280). At act 730, a set of patterned, metalized photovoltaic elements is stacked to form a VMJ solar cell. It should be appreciated that such PV elements can include confined regions of diffuse doping as discussed above. At act 740, the formed VMJ solar cell is processed to facilitate deployment in a PV device, optimize photovoltaic performance, or a combination thereof. Such processing can include various manufacturing steps or procedures such as cutting procedures, polishing procedures, cleaning procedures, integrating procedures, and the like. Such procedures can be directed, at least in part, to expose a specific crystalline plane to sunlight when the formed VMJ solar cell is deployed in a PV device. In one example, processing comprises cutting formed VMJ cell(s) so as to expose or substantially expose <100> crystal planes to sunlight in order to establish the lowest surface states for passivation.

FIG. 8 is a flowchart of an example method 800 for producing solar cells with reduced carrier recombination losses according to aspects described herein. The subject example method 800 is not limited to manufacturing solar cells; example method 800 also can be effected to produce any or substantially any photovoltaic cell. One or more component(s) or module(s) described herein can effect the subject example method 800. At act 810, a set of surfaces of a photovoltaic element (e.g., PV element 110) are patterned with a dielectric coating. Patterning the PV element with the dielectric coating includes utilizing any suitable technique for produce one or more of the dielectric coatings discussed supra. As an example, patterning can proceed through deposition and photolithography techniques. As another example, etching techniques can also be employed to complement or supplement employed patterning protocols. Substantially any or any dielectric material can be employed to coat the set of surfaces. At act 820, a patterned dielectric coating can be utilized to generate confined regions of diffuse doping in the PV element. The patterned dielectric coating can be employed as a mask that dictates the degree of confinement of doping regions. In an aspect, confinement of the doping regions can be nearly two-dimensional, with the doping substantively extending along one dimension and confined along two disparate directions. Confinement of doping regions also can be nearly three-dimensional, wherein doping in the PV element is limited to a set of one or more localized areas substantially smaller than the size of the PV element (see, e.g., FIG. 4). As an example, a striped pattern of dielectric material (e.g., pattern 530), when utilized as a mask for doping, can lead to diffuse doping layers that are substantially confined in two directions, e.g., the diffusion direction towards a center of a slab of nominally non-doped semiconductor material and the direction normal to the pitch or stripe in the patterned coating. Confined regions of diffused doping region(s) reduce volume thereof and mitigate photogenerated carrier recombination losses.

At act 830, an ohmic contact is deposited onto one or more of the patterned surfaces of the PV element. The material for the ohmic contact, can be embodied in substantially any or any conductive material, e.g., a low-resistivity doped semiconductor or a metal. In an aspect, the conductive material nearly matches the thermal coefficient(s) of the semiconductor material e.g., Si; Ge; GaAs, InAs, or other III-V semiconducting compounds; II-VI semiconducting compounds; CuGaSe; CuInSe; CuInGaSe . . . , of the PV element and is suitable for alloying. As indicated supra, pattern(s) of dielectric material coating(s) ensures that deposition of an ohmic contact onto opposing patterned surfaces results in regions of low electrical resistance by aligning metalized regions on disparate surfaces (e.g., 90 degree-misoriented striped openings in patterns 530 and 540 result in metal contact regions aligned along a stacking direction (e.g., z direction 280).

At act 840, a set of patterned, metalized photovoltaic elements is stacked to form a solar cell. The set of photovoltaic elements that form the solar cell spans M elements, with M a natural number determined at least in part by a target operation voltage of the solar cell. In an aspect, the set of PV elements can be homogeneous or heterogeneous. In a homogeneous set each element, or unit cell, in the set is based on the same or substantially the same precursor, whereas in a heterogeneous set each element is based on disparate precursors. Disparate precursors can be based on the same semiconducting compounds, e.g., Si; Ge; GaAs, InAs, or other III-V semiconducting compounds; II-VI semiconducting compounds; CuGaSe; CuInSe; CuInGaSe, but differ in doping type or, for alloyed compounds, in alloying concentrations. In addition, such patterned, metalized PV elements include confined regions of diffuse doping as discussed above. At 850, the solar cell is processed to facilitate deployment in a PV device, optimize photovoltaic performance, or a combination thereof. Processing can include various manufacturing steps or procedures such as cutting procedures, polishing procedures, cleaning procedures, integrating procedures, or the like. Such steps can be intended, at least in part, to expose a specific crystalline plane to sunlight when the formed solar cell is deployed in a PV device. In one example, processing comprises cutting the formed solar cell(s) so as to expose or substantially expose (100) crystal planes to sunlight in order to establish the lowest surface states for passivation. It should be appreciated that the solar cell can be processed to expose or substantially expose other crystal planes, e.g., (qrs) planes such as (311).

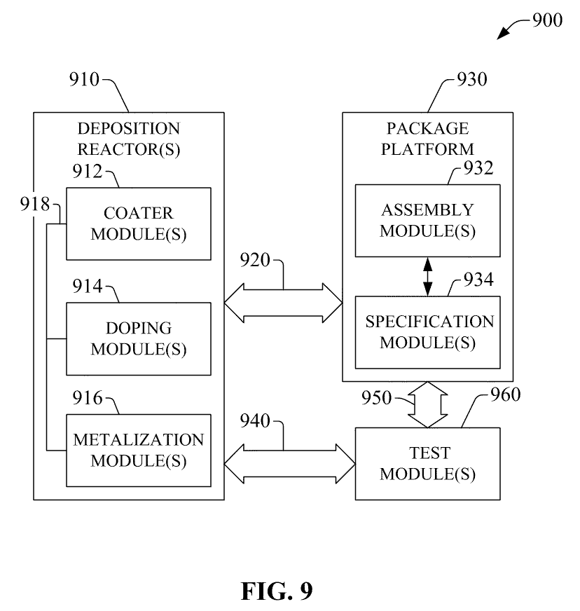

FIG. 9 is a block diagram of an example system 900 that enables fabrication of solar cells in accordance with aspects described herein. Deposition reactor(s) 910 enable processing of semiconductor-base wafers to produce PV elements or unit cells that compose solar cells, e.g., VMJ solar cells, as described herein. Deposition reactor(s) 910 and module(s) therein include various hardware components, software components, or combination(s) thereof, and related electric or electronic circuitry to accomplish the processing. In aspect, coater module(s) 912 allows patterning a surface of a semiconductor wafer or substrate with a dielectric coating. The wafer or substrate can be nominally-undoped or doped, and is the precursor of PV elements utilized for production of the solar cells. As indicating above, patterning can be based upon deposition of the dielectric material via a suitable mask, photolithography, or etching. Deposition reactor(s) 910 also include doping module(s) 914 that allows inclusion of dopants within the semiconductor precursor of the PV elements. Dopants can form diffuse doping layers as described above (see, e.g., FIG. 1 or FIG. 5); however, doping module(s) 914 also afford substantially any type of doping such as epitaxy-based doping, e.g., delta doping. In addition, doping module(s) 914 allow formation of diffusion barriers that can prevent autodoping.

As described above, coating a PV element with a dielectric material can occur prior or subsequent to doping. Doping subsequent to patterned dielectric coating exploits such coating as a mask for generation of confined or nearly-confined doping regions (see, e.g., FIG. 4).

Metallization module(s) 916 enables deposition of metallic layer(s) to a PV element that includes doping regions, extended or confined, and patterned dielectric coating(s). Metallization can be accomplished through deposition of semiconductor material with subsequent doping, or a metal material. In an aspect, such materials have thermal coefficient(s) that matches or nearly matches thermal coefficient(s) of PV element with doping regions.

Deposition reactor(s) 910 can include sputtering chamber(s), epitaxy chamber(s), vapor deposition chamber(s); electron beam gun(s); source material holder(s); wafer storage; sample substrate; oven(s), vacuum pump(s); e.g., turbomolecular pump, diffusion pump; or the like. In addition, deposition reactor(s) 910 can include computer(s), including processor(s) and memories therein, with memories being volatile or non-volatile; programmable logic controller(s); dedicated processor(s) such as purpose-specific chipset(s); or the like. Deposition reactor(s) 910 also can include software application(s) such as operating system(s), or code instructions to effect one or more processing acts, including at least those described supra. Described hardware, software, or combination thereof, facilitate or enable at least a portion of the functionality of deposition reactor(s) 910 and module(s) therein. A bus 918 allows communication of information, e.g., data or code instructions; transfer of materials; exchange of processed elements; and so forth, amongst the various hardware, software, or combination(s) thereof, in deposition reactor(s) 9 10.

Photovoltaic element(s) can be supplied to a package platform 930 for further processing. An exchange link, e.g., a conveyer link, or an exchange chamber and electromechanical components therein, can supply the PV element(s); at least one of the exchange link or exchange chamber illustrated with arrow 920. Assembly module(s) 932 can collect a set of PV element(s) and allow stacking of each of the PV elements through a high-temperature process or step in order to produce a solar cell, e.g., a VMJ solar cell. The stack is transferred to a specification module(s) 934 that completes the solar cell to a determined specification, e.g., the stack is sawed to allow exposure of a particular crystalline plane of the PV elements in the stack that form the solar cell. Such processing can be facilitated or allowed, at least in part, by test module(s) 960, which can determine crystallographic orientation of the PV elements, or unit cells, in the solar cell; such determination can be established via X-ray spectroscopy, e.g., diffraction spectrum and rocking curve spectra.

For quality assurance or to meet specifications, test module(s) 960 can probe precursor materials or processed materials various stages of solar cell manufacturing. As an example, test module(s) 960 can probe density of openings in a patterned dielectric coating of PV element(s) to determine whether such density is adequate for an expected sunlight intensity, or photon flux, in a solar concentrator. As another example, test module(s) can determine defect density that can arise from thermal cycling in a PV element with metallic layers, to establish if the material or process utilized for metallization is adequate. To at least such ends, test module(s) 960 can implement or enable minority-carrier lifetime measurements, X-ray spectroscopy, scanning electron microscopy, tunneling electron microscopy, scanning tunneling microscopy, electron energy loss spectroscopy, or the like. Probe(s) implemented by test module(s) 960 can be in situ or ex situ. Samples of precursor of processed materials or devices, e.g., solar cells, can be supplied to test module(s) via exchange links 940 and 950.

Processing unit(s) (not shown) can effect logic to control at least part of the various processes described herein in connection with operation of system 900. Such processing unit(s) (not shown) can include processor(s) that execute code instructions that effect the control logic; the code instructions, e.g., program module(s) or software applications, can be retained in memory(ies) (not shown) functionally coupled to the processor(s).

What has been described above includes examples of systems and methods that provide advantages of the subject innovation. It is, of course, not possible to describe every conceivable combination of components or methodologies for purposes of describing the subject innovation, but one of ordinary skill in the art may recognize that many further combinations and permutations of the claimed subject matter are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim.

What is claimed is:

1 A photovoltaic cell, comprising:
a monolithic stack of a plurality of semiconductor-based photovoltaic (PV) elements, wherein each element in the plurality of semiconductor-based PV elements includes at least one of a P-type diffuse doping region or an N-type diffuse doping region;
a patterned dielectric coating deposited on at least one the P-type diffuse doping region or the N-type diffuse doping region; and
a metallic layer at the interface amongst elements in the plurality of semiconductor-based PV elements.

2. The photovoltaic cell of claim 1, wherein at least one of the P-type diffuse doping region or the N-type diffuse doping region includes one or more confined regions.

3. The photovoltaic cell of claim 2, wherein a patterned dielectric coating includes at least one of disconnected regions of dielectric material or connected regions of dielectric material.

4. The photovoltaic cell of claim 3, wherein the connected regions of dielectric material includes at least one of a periodic lattice of dielectric areas or a nearly-periodic lattice.

5. The photovoltaic cell of claim 3, wherein the disconnected regions of dielectric material include at least one of a set of stripes oriented at a first angle relative to a <qrs> crystalline direction or a set of stripes oriented at a second angle off the <qrs> crystalline direction, with q, r, and s are Miller indices.

6. The photovoltaic cell of claim 5, wherein density of stripes in at least one of the sets of stripes is dictated at least in part by the radiation intensity at which the plurality of semiconductor-based PV element is expected to operate.

7. The photovoltaic cell of claim 5, wherein a first diffuse doping layer in the PV element is coated with a first pattern of dielectric material and a second diffuse doping layer in the PV element is coated with a second pattern of dielectric material.

8. The photovoltaic cell of claim 7, wherein the first pattern of dielectric material is determined at least in part by recombination losses mechanisms in the first diffuse doping layer.

9. The photovoltaic cell of claim 8, wherein the second pattern of dielectric material is determined at least in part by the recombination losses mechanisms in the second diffuse doping layer.

10. The photovoltaic cell of claim 1, wherein the stack of a plurality of semiconductor-based photovoltaic (PV) elements is processed to substantially expose specific crystalline plane(s) to sunlight.

11. The photovoltaic cell of claim 1, wherein the metallic layer has thermal expansion coefficient(s) that nearly matches thermal expansion coefficient(s) of the semiconductor material of the photovoltaic element.

12. The photovoltaic cell of claim 1, wherein current output upon energy conversion supplied by the semiconductor-based photovoltaic (PV) elements is nearly matched.

13. The photovoltaic cell of claim 1, wherein each element in the plurality of semiconductor-based PV elements is formed through doping of one of an N-type semiconducting precursor, a P-type semiconducting precursor, or an intrinsic semiconducting precursor.

14. The photovoltaic cell of claim 1, wherein a surface of the monolithic stack includes a textured surface with a pattern of cavity formations.

15. A method for producing photovoltaic cells with reduced recombination losses of photogenerated carriers, the method comprising:
patterning a set of surfaces of a photovoltaic (PV) element with a dielectric coating;
depositing an ohmic contact on one or more of the patterned surfaces of the PV element;
stacking a set of patterned PV elements with ohmic contacts to form a vertical multi-junction (VMJ) photovoltaic cell; and
processing the formed VMJ photovoltaic cell to facilitate deployment in a PV device, optimize photovoltaic performance, or a combination thereof.

16. The method of claim 15, wherein one or more surfaces in the set of surfaces include a diffuse doping layer, which spans an extended region or a confined region.

17. The method of claim 15, further comprising utilizing a patterned dielectric coating as a mask to generate confined regions of diffuse doping in the photovoltaic element.

18. The method of claim 15, wherein material for the ohmic contact is a conductive material with thermal expansion coefficient(s) that nearly matches thermal expansion coefficient(s) of the photovoltaic element.

19. The method of claim 15, patterning a set of surfaces of a photovoltaic (PV) element with a dielectric coating includes depositing at least one of a set of stripes oriented at a first angle relative to a <qrs> crystalline direction in the PV element, or a set of stripes oriented at a second angle off the <qrs> crystalline direction in the PV element, with q, r, and s are Miller indices.

20. The method of claim 19, wherein density of stripes in at least one of the sets of stripes is dictated at least in part by the radiation intensity at which the plurality of semiconductor-based PV element is expected to operate.

21. The method of claim 15, wherein the processing act includes cutting the formed VMJ photovoltaic cell to substantially expose (qrs) crystal plane(s) to sunlight, with q, r, and s are Miller indices.

22. The method of claim 15, wherein a stack of patterned PV elements with ohmic contacts that form the VMJ photovoltaic cell are current-matched.

23. An apparatus, comprising:
means for patterning a set of surfaces of a photovoltaic (PV) element with a dielectric coating;
means for depositing a metallic contact on one or more of the patterned surfaces of the PV element;
means for stacking a set of patterned PV elements with metallic contacts to form a vertical multi-junction (VMJ) photovoltaic cell; and
means for processing the formed VMJ photovoltaic cell to facilitate deployment in a PV device, optimize photovoltaic performance, or a combination thereof.

24. The apparatus of claim 23, further comprising means for exploiting a patterned dielectric coating as a mask to generate confined regions of diffuse doping in the photovoltaic element.

25. The apparatus of claim 24, further comprising means for probing at least one of a PV element, a PV element with dielectric coating, a PV element with metallic contacts, or a formed VMJ photovoltaic cell.
